(19) United States
(12) Patent Application Publication
(10) Pub. No.: US 2012/0267240 A1
(43) Pub. Date: Oct. 25, 2012

(54) PHOTOELECTRODE WITH A POLYMER LAYER

(75) Inventors: Lin Ke, Singapore (SG); Surani Bin Dolmanan, Singapore (SG); Szu Cheng Lai, Singapore (SG)

(73) Assignee: Agency for Science Technology and Research, Connexis (SG)

(21) Appl. No.: 13/504,022

(22) PCT Filed: Oct. 26, 2010
(86) PCT No.: PCT/SG2010/000408

§ 371 Date: Jul. 9, 2012

Related U.S. Application Data
(60) Provisional application No. 61/254,831, filed on Oct. 26, 2009.

(51) Int. Cl. C25B 11/04; B05D 5/12; C25B 9/00; H01L 31/0224

(52) U.S. Cl. 204/242; 204/280; 204/290.01; 204/290.03; 204/291; 427/58

(57) ABSTRACT

A photoelectrode including at least one polymer layer is provided. The at least one polymer layer defines the surface of the photoelectrode, or it defines an interlayer within the photoelectrode. The polymer layer can be made of a non-conductive polymer and have a thickness of 100 nm or less.

### CROSS REFERENCE TO RELATED APPLICATIONS

This application makes reference to and claims the benefit of priority of a provisional application for a “Polymer Enhanced Photoelectrode” filed on Oct. 26, 2009 with the United States Patent and Trademark Office, and there duly assigned Ser. No. 61/254,831. The content of said application filed on Oct. 26, 2009 is incorporated herein by reference for all purposes, including an incorporation of any element or part of the description, claims or drawings not contained herein and referred to in Rule 20.5(a) of the PCT, pursuant to Rule 4.18 of the PCT.

### FIELD OF THE INVENTION

The present invention relates to a photoelectrode with a polymer layer. Disclosed is also a method of forming the photoelectrode, as well as a photoelectrochemical cell that includes the photoelectrode.

### BACKGROUND OF THE INVENTION

Dye-sensitized solar cells (DSSC) and water splitting photoelectrochemical cells are two promising candidates of photoelectrochemical cells (PEC) for clean and renewable energy, sources.

The DSSC harnesses solar energy in a low cost and efficient manner through use of organic dyes which release free carriers upon light excitation. A DSSC has a photoelectrode, a counter electrode and a layer of electrolyte between them. The photoelectrode has a transparent conductive film of material, such as indium tin oxide (ITO), deposited on a glass substrate. This transparent conductive film, typically known as the Transparent Conductive Electrode (TCE), serves as the anode for collecting photoelectrons generated from the photoactive layer. The photoactive layer is fabricated on top of the TCE and may include a thin layer of metal oxide, such as titanium dioxide (TiO₂) or zinc oxide (ZnO), coated with photosensitive dye molecules. This metal oxide layer is highly porous so as to create a large internal surface area for anchoring photosensitive dye molecules coated on top of it. The counter electrode is typically made of a metal, such as platinum (Pt). A thin layer of electrolyte, such as iodide, which serves as a mediator for the redox reaction in the cell, is present between the two electrodes. For a water splitting PEC, the photoelectrode and counter electrode are immersed in a water-based electrolyte. Upon solar irradiance, redox reaction takes place and water is decomposed into hydrogen and oxygen.

As the photoelectrodes in both the DSSCs and water splitting PECs are immersed in an ionic electrolyte medium, they are subjected to chemical corrosion from the electrolyte. This problem is aggravated in the case of DSSCs, where organic dye is very susceptible to corrosion and dissolution in the electrolytic medium.

To address this problem, attempts have been made to coat the photoelectrodes with a thin film of material, which acts as a barrier between the electrode and the electrolyte. Materials used include metal oxides, such as ITO, and conductive polymers, such as polypyrrol. However, these attempts are considered ineffective. Metal oxides, which are themselves prone to corrosion, do not adhere strongly to the underlying photoactive materials and to a much lesser extent on the dye layer. Conductive polymers such as polypyrrol are hydrophilic in nature, which results in a minimum thickness in the micrometer range required to coat the photoelectrodes such that the barrier is impermeable to the electrolyte. In the case of a photoelectrode with highly porous photoactive surface, a thick protective film reduces electron transfer efficiency between electrode and electrolyte, since the effective surface area for contact with the electrolyte is reduced. Solar absorption losses within the protective film also increase in some cases when light has to penetrate through a thicker film before reaching the photoactive layer.

In addition, there is a need for better adhesion between the anode and the photoactive layer such that internal charge transfer efficiency and lifetime of the photoelectrode can be improved.

It is accordingly an object of the present invention to provide a photoelectrode and a method of forming the same that avoids at least some of the above named difficulties in current photoelectrodes. This object is solved by the photoelectrode and the method of producing the same according to the independent claims.

### SUMMARY OF THE INVENTION

In a first aspect the present invention provides a photoelectrode. The photoelectrode includes at least one polymer layer made of a non-conductive polymer with a thickness of about 100 nm or less. The at least one polymer layer either defines the surface of the photoelectrode, or the polymer layer defines an interlayer within the photoelectrode, or both.

In a second aspect the invention provides a method of producing a photoelectrode. The method includes providing a substrate. The method also includes forming a polymer layer above the substrate. The polymer layer is made of a non-conductive polymer and has a thickness of about 100 nm or less.

In some embodiments the method further includes forming a conductive layer, such as a transparent conductive layer, above the substrate. In some embodiments the method further includes forming a photoactive layer above the substrate.

In a third aspect, the present invention is directed to a photoelectrode comprising a photoactive layer, a conductive layer and at least one polymer layer. The at least one polymer layer is made of a conductive polymer and is arranged between the photoactive layer and the conductive layer.

In some embodiments the conductive layer is transparent.

In a fourth aspect, the present invention relates to a method for of producing a photoelectrode comprising
(a) providing a substrate,
(b) forming a conductive layer above the substrate,
(c) forming a polymer layer made of a conductive polymer above the conductive layer; and
(d) forming a photoactive layer above the polymer layer.

In a fifth aspect the invention provides a photoelectrochemical cell. The photoelectrochemical cell includes a photoelectrode according to the invention. The photoelectrochemical cell may for example be a photovoltaic cell or a water splitting photoelectrochemical cell.

### BRIEF DESCRIPTION OF THE DRAWINGS

The invention will be better understood with reference to the detailed description when considered in conjunction with the non-limiting examples and the accompanying drawings.

FIG. 1 depicts images of Atomic Force Microscopy (AFM) on an ITO surface (A) and ITO covered with a layer of Parylene® (B).

FIG. 2 depicts transmittance curves of glass/ITO/Parylene® (10 nm, rough) and glass/ITO/Parylene' (10 nm, smooth) (A) and absorption curves of glass/ITO/Parylene® (10 nm, rough) and glass/ITO/Parylene® (10 nm, smooth) (B), with Parylene® defining the surface.

FIG. 3 shows data of UV photoelectron spectroscopy on ITO covered with a layer of Parylene®.

FIG. 4 depicts a comparison of I-V (A) and efficiency curves (B) of TiO₂ versus TiO₂ dye-sensitized PEC cells coated with Parylene®.

FIG. 5 depicts lifetime curves of glass/ITO/TiO₂/Parylene® and glass/ITO/TiO₂/dye.

FIG. 6 shows UV-Vis absorbance spectra of glass/TiO₂/dye and glass/TiO₂/dye/Parylene®.

FIG. 7 depicts I-V and efficiency curves of ZnO versus ZnO PEC cells with a Parylene® interlayer.

FIG. 8 shows secondary ion mass spectroscopy on glass/FTO/ZnO/Parylene® and glass/FTO/ZnO. On the structure glass/FTO/ZnO/Parylene® (FTO=fluorine doped tin oxide), with Parylene® defining the surface, both the O and the Zn profile become very stable after hours of stress, when compared to the structure without a Parylene® layer.

### DETAILED DESCRIPTION OF THE INVENTION

A photoelectrode according to the present invention is used in a photoelectrochemical cell for the conversion of electromagnetic energy to another energy form or energy source or to drive or facilitate a chemical reaction. A photoelectrochemical cell has a photoelectrode, a counter electrode and an electrolytic media in-between. In a photoelectrochemical cell, the photoelectrode typically includes a photoactive layer, a conductive layer and a substrate. The counter electrode may include or consist of a metal (e.g. Pt) or a semiconductor. A respective photoelectrochemical cell may for example be a photovoltaic cell that is capable of generating electrical energy upon irradiation of the photoelectrode. The photoelectrochemical cell may also be a photogeneration cell, which is capable of splitting water into oxygen and hydrogen. Herein a photoelectrochemical cell capable of forming oxygen and hydrogen gas from water is called a water-splitting photoelectrochemical cell. In a water-splitting photoelectrochemical cell (photogeneration cell) irradiation of the photoelectrode causes electrolysis of water to hydrogen and oxygen gas. The function of a photoelectrochemical cell is based on the fact that photons striking a photoactive material of the photoelectrode can release photoelectrons from the material. These photoelectrons can be transported to the conductive layer, which is in electrical contact, including electrically connected, to the counter electrode via an external load. In this process, the loss of electrons in the oxidised photoactive material is replenished by the redox couple in the electrolyte. In a dye-sensitized solar cell, the redox coupler typically includes or consists of I⁻ and I₋, whereby r donates electrons to the oxidised photoactive organic dye. In this process, I⁻ is oxidised to I₃⁻, which is then regenerated back to I⁻ by electrons at the counter electrode. In a water-splitting cell, the electrolyte is a water-based media such as a potassium hydroxide solution, and a similar concept applies mutatis mutandis so that water is oxidised to oxygen at the photoelectrode and reduced to hydrogen at the counter electrode. In a water-splitting cell, however, there is no regeneration of redox-coupler.

A photoelectrochemical cell that includes a photoelectrode according to the invention may be any photoelectrochemical cell such as a photoelectrolytic cell, a photocatalytic cell, a light emitting cell or a dye-sensitized solar cell. In a photocatalytic cell light serves in accelerating the rate of a reaction, whereas in a photoelectrolytic cell a reaction is driven by irradiation, e.g. light, in the contra-thermodynamic direction.

A photoelectrochemical cell, and in particular a photovoltaic cell, is often called a solar cell since the typical source of electromagnetic energy used is sunlight. Nevertheless the use of visible light, corresponding to a wavelength range of about 400 to about 700 nanometers, is merely one embodiment of a use of a photoelectrode according to the invention. A photoelectrode according to the invention may be designed for use at electromagnetic radiation of any wavelength, including a distinct wavelength, a set of distinct wavelengths or any region of the electromagnetic spectrum. A further example of a region of the electromagnetic spectrum is ultraviolet light, corresponding to a wavelength range of about 30 to about 400 nanometers.

The photoelectrochemical cell has a photoelectrode, a counter electrode and an electrolyte, the latter for example being provided in a solution or in the form of a polymer such as polyethylenimine. The photoelectrode may in some embodiments be taken to define an anode. The counter electrode may in some embodiments be taken to define a cathode. The photoelectrode, also called working electrode, typically includes a photoactive layer. The term “layer” as used herein means a continuous region of a material that can be of uniform or non-uniform thickness. A layer may thus have a consistent thickness or have a varying thickness, i.e. a different thickness at different positions. In case the layer is of varying thickness, its thickness, when referred to, is intended to mean its maximal thickness. In some embodiments, for example in case of a photoactive layer (see below), a layer may include a plurality of sublayers. The term “layer” is not itself intended to imply any specific manufacturing method, step or material.

In a photoelectrode according to the present invention the photoactive layer may include a semiconductor such as a n-type semiconductor. An illustrative example of a n-type semiconductor is a metalloid that includes a dopant. The metalloid may for instance be a group IV element, e.g. silicon, germanium or tin, doped with a group V element such as phosphorus, arsenic or antimony. A further example of a semiconductor that may be provided in the photoactive layer is a metalloid oxide such as silicon oxide, a metal oxide, a metal selenide or a metal sulphide. An illustrative example of a metal oxide is titanium dioxide, for example in the form commercially available as e.g. Degussa P25. Further examples of a suitable metal oxide include, but are not limited to, titanium oxide (TiO₂), tin oxide (SnO), zinc oxide (ZnO), niobium oxide (Nb₂O₅), zirconium oxide (ZrO₂), cerium oxide (CeO₂), aluminum oxide (Al₂O₃), nickel oxide, tungsten oxide (WO₃), strontium titanate (SrTiO₃), CuAlO₂, Zn₂Sna₄, SrCu₂O₂ and BaTiO₃. The metal oxide may be include a dopant such as a metal, a further metal oxide, a metal salt, a metalloid, a salt of a metalloid, a metalloid oxide or a non-metal element or compound, for instance nitrogen or fluorine. Two illustrative examples of a metal sulfide are cadmium sulfide (CdS), MoS₂ and CuInS₂. Examples of a metal selenide include, but are not limited to, CdSe, WSe₂, MoSe₂, CuInSe₂ and copper indium gallium selenide, having a chemical formula of CuInₓGa₍₁₋ₓ₎Se₂, where x can be any value from 0 to 1. In some embodiments the semiconductor used may be or include monocrystalline silicon, monocrystalline germanium, monoc_{ry}stalline silicon-germanium, amorphous silicon, amorphous germanium, amorphous silicon-germanium or a combination thereof A further example of a semiconductor is a nitride of a metal of group 13 of the Periodic Table of Elements, such as aluminium nitride, gallium nitride or indium nitride. Yet a further example of a suitable semiconductor is a compound of a metal and a metalloid such as gallium arsenide, GaAs, or cadmium telluride, CdTe.

The photoactive layer may in some embodiments be mesoporous. It may in some embodiments be composed of, including consist of, nanoparticles, e.g. TiO₂ nanoparticles. In some embodiments the photoactive layer includes a semiconductor such as a metal oxide in the form of nanowires, nanorods, nanotips or nanotubes such as ZnO nanowires, ZnO nanotips, ZnO nanorods, TiO₂ nanotubes or ZnO nanotubes.

The photoactive layer includes a photoactive material. In some embodiments the photoactive layer includes or is of a photoactive oxide, which is a metal oxide or a metalloid oxide. There may for instance be provided as or in the photoactive layer a doped oxide or an oxide with a controlled oxygen vacancy content. Such an oxide may be epitaxial, polycrystalline or amorphous. Suitable examples of an oxide include, but are not limited to, SrTiO₃, tungsten trioxide (WO₃), iron oxide (Fe₂O₃), titanium dioxide (TiO₂) or a combination thereof In typical embodiments the photoactive layer includes a chromophore, i.e. matter that absorbs light in a selected spectral region of electromagnetic radiation. In some embodiments the photoactive layer includes a photosensitizer, which is typically a photosensitive dye molecule (e.g. Gratzel, M, Nature (2001) 414, 338-344; Halme, J, et al., Advanced Energy Materials (2010) 22, E210-E234; Hagfeldt, A, et al., Chem Rev (2010) doi: 10.1021/cr900356p). Examples of an organic dye include, but are not limited to, an azo dye, a quinine dye, a quinone imine dye, a quinacridone dye, a squarylium dye, a cyanine dye, a merocyanine dye, a triphenylmethane dye, a xanthene dye, a porphyrin dye, a perylene dye, an Indigo dye and a naphthalocyanine dye. Examples of a metal complex dye include, but are not limited to, a complex of Cu, Ni, Fe, Co, V, Sn, Si, Ti, Ge, Cr, Zn, Ru, Mg, Al, Pb, Mn, In, Mo, Y, Zr, Nb, Sb, La, W, Pt, Ta, Ir, Pd, Os, Ga, Tb, Eu, Rb, Bi, Se, As, Sc, Ag, Cd, Hf, Re, Au, Ac, Tc, Te and Rh. Two illustrative examples of a molecule that is capable of forming a complex with a metal ion are a phthalocyanine compound and a porphyrine compouns. A further illustrative example of a metal complex that can be used as a dye is a ruthenium bipyridine or ruthenium tripyridine dye. An illustrative list of examples of ruthenium bipyridine and tripyridine dyes can for example be found in Hagfeldt et al. (supra). Illustrative examples of a dye that is free of a metal complex are an indoline dye, a tetrahydroquinoline dye, a coumarin dye, a merocyanine dye, a perylene dye or a squaraine.

In some embodiments the photoactive layer includes two or more sublayers, each of which may include a different chromophore, e.g. photosensitive dye. In some embodiments the photosensitiser is or includes a ruthenium, an osmium or an iron complex or a combination of two or three transition metals in one supramolecular complex. The photoactive layer may in some embodiments also include an electron donor or an electron acceptor in a functionalized polypyrrole film, as disclosed by Deronzier (Polymers for Advanced Technologies (1994) 5, 193-199). In some embodiments the photoactive layer includes an electropolymerized outer sublayer of 4-methyl-4′-vinyl-2,2′-bipyridine in the form of a ruthenium complex (Moss, J A, Inorganic Chemistry (2004) 43, 1784-1792). The photoactive layer generally serves in forming an electron-hole pair by absorbing electromagnetic radiation such as visible light. A semiconductor (supra) such as a transition metal oxide included in the photoactive layer, can in this case serve in transferring photoelectrons to the conductive layer. A photoelectrode with a photoactive layer such as a layer that includes a dye can be applied to photovoltaics as well as to solar conversion reactions such as water splitting. Accordingly, a photoelectrode with a photoactive layer may for example be included in a photovoltaic cell and a water splitting photoelectrochemical cell.

In some embodiments a photoelectrode of the invention has a photoactive layer that defines the surface of the photoelectrode. In such an embodiment a polymer layer is arranged between the photoactive layer and the substrate, e.g. between the photoactive layer and the conductive layer. In some embodiments the surface of the photoelectrode is defined by a polymer layer. In such an embodiment the photoactive layer is arranged between the substrate and the polymer layer. A further polymer layer may in such an embodiment be arranged between the photoactive layer and the substrate.

In some embodiments a photoelectrode according to the invention further includes a conductive layer. The conductive layer may generally include a metal, a metalloid, a metal oxide or a metalloid oxide. A respective conductive layer may in some embodiments be of (i.e. consist of) or include an at least essentially transparent, including fully transparent, conductive metal oxide such as tin oxide, zinc oxide, indium oxide and indium tin oxide. A respective metal oxide may in some embodiments include a dopant. Illustrative examples of a doped metal oxide are fluorine doped tin oxide, aluminium doped zinc oxide, indium-doped cadmium-oxide and gallium doped zinc oxide. The conductive layer is typically arranged on the substrate in such a way that it is in contact with the substrate. In some embodiments the conductive layer is sandwiched between the substrate and the photoactive layer, i.e. in contact with both the substrate and the photoactive layer.

The conductive layer is in some embodiments arranged adjacent to a substrate. In such embodiments at least a portion of the photoactive layer may be in contact with the substrate. The substrate is of, i.e. consists of, solid matter. It may in some embodiments be of, or include, a metalloid, e.g. silicon. The substrate may be of, or include, a metal such as iron, titanium or nickel, vanadium, zirconium, niobium, vanadium, chromium, manganese, cobalt, zinc, aluminium or molybdenum, or an oxide thereof It may in some embodiments be of or include steel. The substrate may also be of ceramics or oxide ceramics. Examples of ceramics include, but are not limited to, silicate ceramics, oxide ceramics, carbide ceramics or nitride ceramics. In some embodiments the substrate is of transparent material such as glass, quartz and transparent plastic material. In some embodiments the substrate may be a glass fiber. A transparent substrate will generally be selected in embodiments where the photoelectrode is designed in such a way that the substrate is to be arranged between the source of electromagnetic radiation and the photoactive layer. The term “transparent” when used herein, means that matter allows at least 60%, at least 70%, at least 80%, at least 85%, at least 90%, at least 95%, at least 97% at least 99% or more, of the incident electromagnetic radiation of interest, e.g. visible light, to pass through the substrate. Where a transparent substrate is used, the substrate that may allow light of a defined wavelength, or electromagnetic radiation within a certain range of the electromagnetic spectrum, for example visible light, infrared light, X-ray and/or UV light, to pass through. Typically this wavelength or range of the electromagnetic spectrum overlaps, includes or coincides with the wavelength(s) or range of the electromagnetic spectrum at which the photoelectrode is capable of converting energy (supra). Examples of a suitable plastic material include, but are not limited to, a polymethacrylate (e.g. polymethyl-methacrylate (PMMA) or a carbazole based methacrylate and a dimethacrylate), polystyrene, polyethylene terephtalate, polyethylpne naphthalene, polycarbonate, polycarbonate and a polycyclic olefin.

In some embodiments a photoelectrode according to the invention has a substrate, a photoactive layer and one or more polymer layers. In some embodiments one of the one or more polymer layers, which is made of or includes a non-conductive polymer, may define a surface of the photoelectrode. In some embodiments one of the one or more polymer layers, which is made of or includes a non-conductive polymer, may be arranged, for example sandwiched, between the conductive layer and a photoactive layer. In other embodiments where the polymer layer is arranged between the conductive layer and a photoactive layer, the polymer layer is made of a conductive polymer, such as polypyrrol, a polyaniline or a poly(thiophene) (see also below). Where a respective polymer layer is arranged between the conductive layer and the photoactive layer, the photoactive layer may define the surface of the photoelectrode. Alternatively, the photoelectrode may further comprise a polymer layer of a non-conductive polymer, for example as defined herein, arranged above the photoactive layer and defining the surface of the electrode. In some embodiments at least one of the one or more polymer layers is at least essentially, including entirely, free of a metal complex, in particular of a transition metal complex. In some embodiments all polymer layers that are included in the photoelectrode are at least essentially, including entirely, free of a metal complex, in particular a transition metal complex.

The photoelectrode of the invention includes one or more polymer layers. In one embodiment at least one such polymer layer included in the photoelectrode is of or includes one or more non-conductive polymers. This polymer layer is therefore free of conductive polymers. At least one such polymer layer is arranged above the photoactive layer. In some embodiments the respective polymer layer defines the surface of the photoelectrode. In some embodiments where the photoelectrode has a photoactive layer the polymer layer defines an interlayer that is arranged between the photoactive layer and the photoactive layer. Typically the polymer of this polymer layer is free of photoactive material. It does thus for example not contain an organic dye.

As noted above, the photoelectrode of the invention has a polymer layer that is of (i.e. consists of) or includes a non-conductive polymer. An example of a non-conductive polymer is a fluoropolymer such as fluoroethylenepropylene (FEP), polytetrafluoroethylene (PFTE, Teflon®), ethylene-tetrafluoroethylene (ETFE), tetrafluoroethylene-perfluoromethyl-vinylether (MFA), vinylidene fluoride-hexafluoropropylene copolymer, tetrafluoroethylene-hexafluoropropylene copolymer, polyvinylidenedifluoride (PVDF), vinylidene fluoride-hexafluoropropylene-tetrafluoroethylene terpolymer, perfluoromethyl vinyl ether-tetrafluoro-ethylen copolymer, perfluoroalkoxy copolymer (PFA), poly(vinyl fluoride), polychlorotri-fluoroethylene, a fluorosilicone or a fluorophosphazene. A fluoropolymer is inert against most corrosive media. Parylene® is a poly(1,4-xylylene), such as Parylene® N, which is obtained by polymerisation of di-p-xylylene ([2.2]paracyclophane). Parylene® is accordingly a non-polar polymer that is hydrophobic. Parylene C is (poly(2-chloro-p-xylylene)), obtained by polymerisation of monochloro para-xylylene. Parylene D is obtained by polymerisation of dichloro para-xylylene (poly(2,5-dichloro-p-xylylene), Parylene AF-4, Parylene SF and Parylene HT are [poly(α,α,α,α-tetrafluoro-p-xylylene)], with Parylene AF-4 being obtained in a three-step synthesis. Parylene A is obtained by polymerisation of (4-amino[2.2]paracyclophane), Parylene AM is (poly(aminomethyl[2,2]-paracyclophane), Parylene VT-4 is poly(tetrafluoro-p-xylylene), Parylene CF is of the same structure as Parylene VT-4, and Parylene X is a copolymer of poly(ethynyl-p-xylylene) and poly(p-xylylene). Further examples of Parylenes are Parylene SR/HR, high-thermally-stable grades of parylene N and parylene D. Further examples of a nonconductive polymer are a polyimide, a polyetherimide, a polyether, a polyester, a polyurethane, a polycarbonate, a polysulfone, and a polyethersulfone. The polymer layer may also include a combination of nonconductive polymers. A polymer included in the polymer layer can be a synthetic polymer, a naturally occurring polymer or a combination thereof As used herein the term “synthetic polymer” refers to polymers that are not found in nature, including polymers that are made from naturally occurring biomaterials.

A non-conductive polymer included in the polymer layer may in some embodiments be an amphiphilic polymer. The term amphiphilic refers to a polymer that is soluble in both polar and non-polar liquids. The amphiphilic properties of the polymer are due to the presence of both polar and non-polar moieties within the same polymer. An amphiphilic polymer included in the polymer layer may for example include a monomer unit of a carboxylic acid, an amide, an amine, an alkylene, a dialkylsiloxane, an ether and an alkylene sulphide. In some embodiments it may include or be a polycarboxylic acid, a polyamide, a polyamine, a polyalkylene, a poly(dialkylsiloxane), a polyether, a poly(alkylene sulphide) and any combination thereof.

A non-conductive polymer included in the polymer layer may in some embodiments be a hydrophilic polymer, i.e. a polymer with polar moieties, rendering the polymer soluble in water. Examples of a hydrophilic polymer include, but are not limited to an acrylamide polymer such as poly(N-isopropylacrylarnkle), poly(dimethyl acrylamide), or poly(acrylamide-co-acrylic acid), a methacrylate polymer such as poly-N-hydroxy-ethylacrylamide, poly[N-(2-hydroxypropyl)methacrylamide], poly(l-vinylpyrrolidone-co-2-dimethylaminoethyl methacrylate), poly(-hydroxyethyl methacrylate), poly(-hydroxpropyl methacrylate), poly(N-isopropylacrylamide-co-methacrylic acid), an acrylic acid based polymer such as poly(acrylic acid), fluoropolyacrylate, poly(methoxy polyethylene glycol methacrylate), 3,4-epoxy-cyclohexylmethylmethacrylate or poly(acrylic acid-co-maleic acid), or a maleic anhydride copolymer such as poly(ethylene-alt-maleic anhydride), poly(isobutylene-co-maleic acid) or poly(methyl vinyl ether-alt-maleic anhydride).

In embodiments where an electrolyte in solution is used and where a hydrophilic polymer is used as a surface layer, it may be particularly advantageous to select a polymer, e.g a hydrophilic polymer, that has a low or no permeability to the respective electrolyte. In this regard a low permeability means a permeability that allows for significantly lower contact of electrolyte molecules with the layer that is arranged between the polymer layer and the substrate, e.g. a photoactive layer or a conductive layer. As a result, over time less corrosion of the layer that is arranged between the polymer layer and the substrate occurs when compared to a photoelectrode without a polymer layer defining its surface. In some embodiments the polymer, e.g. the hydrophilic polymer, is free of pores or pinholes. Thereby direct contact between the ambience and a layer that is arranged between the polymer layer and the substrate is prevented. In some embodiments a layer of a polymer such as a hydrophilic polymer is impermeable to water, thereby also reducing corrosion when compared to a photoelectrode without a polymer layer defining its surface. The use of a, polymer such as a hydrophilic polymer may be particularly suitable in allowing conformal coating. A polymer such as a hydrophilic polymer may also have an intrinsic chemical resistance, thereby protecting a layer that is arranged between the polymer layer and the substrate.

In some embodiments a non-conductive polymer included in the polymer layer is an ion conducting polymer. Ion conducting polymers are typically polymer membranes. Examples of such commercially available polymer electrolyte membranes are those of Nafion (Dupont) which are perfluorosulfonic polymers, and Dais Corporation, which are non-fluorinated membranes made of triblock copolymers. In some embodiments a polymer included in the polymer layer—including ‘the’ polymer, in embodiments where the polymer layer is defined by a single polymer—is non-ion conducting. In some embodiments a polymer included in the polymer layer is ion-permeable. Such a polymer is typically an ion exchange resin, which is often based on a styrene-divinylbenzene copolymer, carrying positively or negatively charged functional groups. A cation exchange resin has negatively charged functional groups such as COOH⁻or SO³⁻, whereas an anion exchange resin has positively charged functional groups such as a quaternary ammonium salt. In some embodiments a polymer included in the polymer layer is ion-impermeable.

In some embodiments of a photoelectrode according to the invention the polymer layer is arranged above the photoactive layer. At least a portion of the polymer layer, including the entire polymer layer, may for example be in contact with the photoactive layer. In some embodiments where the polymer layer defines an interlayer within the photoelectrode, the polymer layer is arranged between a photoactive layer (supra) and a conductive layer (supra). In such an embodiment at least a portion of the photoactive layer, including the entire photoactive layer, may be in contact with the polymer layer. In some embodiments the polymer layer is sandwiched between the photoactive layer and the conductive layer. In such an embodiment the polymer layer is in contact with both the photoactive layer and the conductive layer.

In embodiments where a polymer layer defines an outerlayer, i.e. a layer defining the surface of the photoelectrode, the polymer layer is in some embodiments arranged in the form of an ultra-thin film, in particular of nanometer thickness so as to substantially reduce the barrier to electron transfer between electrode and electrolyte. A polymer layer that defines the surface of the photoelectrode has in some embodiments a thickness of about 100 nm or less. It may for example have a thickness of about 90 nm or less, about 80 nm or less, about 70 nm or less, about 60 nm or less, about 50 nm or less, about 40 nm or less, about 30 nm or less, about 20 nm or less or about 10 nm or less. It may for example have a thickness in the range from about 1 nm to about 100 nm, about 1 nm to about 80 nm, about 10 nm to about 80 nm less, about 5 nm to about 90 nm or about 5 nm to about 75 nm. A polymer layer of a thickness in such a nanometer range allows electrons to be transferred across the material by a tunnelling mechanism. Therefore a non-conductive polymer can be used in the polymer layer of a photoelectrode according to the invention.

In embodiments where a polymer layer is arranged, including sandwiched, between the conductive layer and a photoactive layer, a polymer layer made of a conductive polymer may be of any desired thickness. In embodiments where the sandwiched polymer layer is made of non-conductive polymers, it is advantageous to select a thickness of such a polymer layer that is in the nanometer range. A polymer layer of a non-conducting polymer may have a thickness of about 100 nm or less. It may for example have a thickness of about 90 nm or less, about 80 nm or less, about 70 nm or less, about 60 nm or less, about 50 nm or less, about 40 rim or less, about 30 nm or less, about 20 nm or less or about 10 nm or less. It may for example have a thickness in the range from about 1 nm to about 100 nm, about 1 nm to about 80 nm, about 10 nm to about 80 nm less, about 5 nm to about 90 nm or about 5 nm to about 75 nm.

In some embodiments a photoelectrode of the invention has a substrate, a photoactive layer and one or more polymer layers. One of the one or more polymer layers defines a surface of the photoelectrode or is arranged between the photoactive layer and the substrate. Where the polymer layer defines the surface of the photoelectrode, the polymer layer is of a non-conductive polymer and has a thickness of about 100 nm or less. Where the polymer layer is arranged between the photoactive layer and the substrate, the photoactive layer defines the surface of the photoelectrode. Where the polymer layer is arranged between the photoactive layer and the substrate, generally any polymer can be included in such a polymer layer, as long as it can be adequately deposited on the conductive layer of the electrode, where present. In some embodiments a respective polymer layer, arranged between the photoactive layer and the substrate, is of or includes a conductive polymer, i.e. an organic electroconductive polymer that is capable of conducting electricity. Where the polymer layer is arranged between the photoactive layer and the substrate, it is in some embodiments arranged between the photoactive layer and a conductive layer (supra).

In some embodiments a photoelectrode of the invention has a photoactive layer, a conductive layer and one or more polymer layers. The respective photoactive layer may be or include a sublayer that includes or consists of a semiconductor (supra). At least one of the one or more polymer layers is of or includes a conductive polymer. This polymer layer of the one or more polymer layers, which is of or includes a conductive polymer, is arranged between the photoactive layer and the conductive layer. It may in some embodiments be sandwiched between the photoactive layer and the conductive layer. In some of these embodiments the photoelectrode also includes a substrate.

Accordingly, in some embodiments a polymer layer that defines an interlayer is of or includes a conductive polymer. A conductive polymer is generally a conjugated polymer in that it has aromatic and/or unsaturated monomer units that define a conjugated structure in the polymer. In a conjugated system a plurality of double (e.g. C═C, C═O or C═N) and/or triple bonds (e.g. C≡C) between neighbouring atoms may for example be arranged as alternating with a respective C—C single bonds. A conjugated system allows for electrons of π-orbitals to be delocalized, an effect that can be depicted in the form of resonance structures. A conjugated system may also include a π-orbital of an atom that is adjacent to a double or triple bond, such as in the case of the moiety —C═C—N—C═C—. Examples of a conductive polymer include a poly-(pyrrole), a polycarbazole, poly(N-vinyl carbazole), a polyindole, a polyazepine, a polyaniline, a poly(thiophene) such as poly(3,4-ethylenedioxythiophene), poly(p-phenylene), poly(p-phenylene vinylene), a poly(p-phenylene sulfide), a poly(acetylene), a poly(fluorene), a polypyrene, a polyazulene, and a polynaphthalene or a copolymer such as a copolymer of p-phenylene and o-phenylene, a copolymer of pyrrole and thiophene or a copolymer of juglone and 5-hydroxy-3-thioacetic-1,4-naphthoquinone (Reisberg, S., et al., Anal. Chem. (2005) 77, 10, 3351-3356). A polymer layer that defines an interlayer, if present, may also include a combination of conductive polymers. It may also include a combination of conductive polymers and nonconductive polymers.

As explained above a polymer layer that defines an interlayer may also be of or include a non-conductive polymer. The use of a non-conductive polymer, in particular of a thin film of nanometer thickness, in-between the back electrode and photoactive layer improves the adhesion and smoothness of the interface, thereby improving efficiency and lifetime of the photoelectrode. It is advantageous to provide a layer of a non-conductive polymer of nanometer thickness, since electrons are transferred across the material by a tunnelling mechanism. Electrically non-conductive polymers, such as Parylene®, Polyimide and Teflon (supra), can therefore be used in a respective polymer interlayer.

The inventors have found that sandwiching a polymer layer between the conductive layer and a photoactive layer improves the adhesion of the latter. A respective polymer interlayer further increases the (solar) conversion efficiency of the photoelectrode. The (solar) conversion efficiency indicates the amount of electrical power formed with a defined amount of electromagnetic radiation, e.g. solar irradiation. The inventors have further found that a polymer layer that defines the surface of the photoelectrode increases the lifetime thereof. Further a polymer layer as a surface increases the absorption of light by the photoelectrode.

The formation of a photoelectrode of the invention may be carried out by providing a substrate and successively depositing layers on the substrate. As noted above, in some embodiments a conductive layer is formed above the substrate. The conductive layer may for example be deposited on the substrate such that at least a portion of the conductive layer, including the entire conductive layer, is in contact with the substrate. In some embodiments a substrate is provided, which is already coated with a conductive layer. Further a photoactive layer may be formed above the substrate. In embodiments where no conductive layer is formed above the substrate, the photoactive layer may be deposited on the substrate. Following deposition of the photoactive layer, in such an embodiment at least a portion of the photoactive layer, including the entire photoactive layer, is in contact with the substrate. In embodiments where a conductive layer has been formed above the substrate the photoactive layer may be deposited on the conductive layer. In such an embodiment, following deposition of the photoactive layer, at least a portion of the photoactive layer, including the entire photoactive layer, is in contact with the conductive layer.

Further, a polymer layer is formed above the substrate. The polymer layer may in some embodiments be formed above the photoactive layer. It may for instance be deposited on the photoactive layer, so that at least a portion of the polymer layer, including the entire polymer layer, is in contact with the photoactive layer. In some embodiments the photoactive layer is deposited on the polymer layer, so that at least a portion of the photoactive layer, including the entire photoactive layer, is in contact with the polymer layer.

Any suitable deposition technique may be used. Numerous methods of selectively depositing matter on a surface are established in the art. As an example, a printing technique such as microcontact printing, a sputtering technique, electroless and/or electrolytic plating, chemical vapour deposition, physical vapour deposition or a chemical bath deposition may be used. The respective deposition process, such as sputtering, a sol-gel process or a chemical vapour decomposition coating process used in the present invention can be performed according to any protocol. Depositing a conductive layer onto the substrate, e.g. providing an ITO coating, may for instance be carried out by sputter deposition. A ZnO layer may for example also be deposited by means of chemical bath deposition, a process developed for forming ceramic films. Depositing a polymer may for instance be carried out by means of chemical vapour deposition or by polymerisation on the surface. A metal oxide, a metalloid oxide or a mixture of metal and/or metalloid oxides, it may for example be deposited by flame hydrolysis deposition (FHD), plasma enhanced chemical vapour deposition (PECVD), inductive coupled plasma enhanced chemical vapour deposition (ICP-CVD) or the sol-gel method. In some embodiments the photocatalytic matter is deposited by means of the sol-gel process.

In embodiments where the photoactive layer includes or is a metal oxide or metalloid oxide it may in some embodiments be obtained by means of a sol-gel process. A suitable precursor of the metal oxide/metalloid oxide, e.g. a silicon alkoxide or a titanium alkoxide, may for instance be used, for example in the presence of a template, such as Pluronic P123. The respective sol may be generated by hydrolysis of the metal oxide/metalloid oxide. The hydrolysis of a silicon alkoxide is thought to induce the substitution of OR groups linked to silicon by silanol Si-OH groups, which then lead to the formation of a silica network via condensation polymerisation. As an illustrative example, a titanate sol may be generated by hydrolysis of tetrabutyl-titanate or tetrapropyl-titanate. Any suitable protocol, such as sol-gel protocols using acid-catalysed, base-catalysed and two-step acid-base catalysed procedures may be followed. After the photoactive layer has been formed, it may in some embodiments subsequently be treated by oxidation, hydrogen reduction, or exposed to water vapour. Such a treatment can reduce or increase lattice defects in the photoactive layer. An increase in lattice defects in the photoactive layer may increase electrical conductivity.

In some embodiments a method of forming a photoelectrode according to the invention includes providing a substrate. The method further includes depositing a photoactive layer above, including on, the substrate. The method further includes depositing a polymer layer above the photoactive layer. Depositing a polymer layer above the photoactive layer is carried out in such a way that the polymer layer defines the surface of the photoelectrode or that the polymer layer is arranged between the substrate and the photoactive layer. Where the photoactive layer defines the surface of the photoelectrode, depositing the polymer layer includes forming a layer of a polymer of about 100 nm or less. Where the polymer layer is arranged between the photoactive layer and the substrate, depositing the polymer layer includes depositing the photoactive layer above the polymer layer. As a result the polymer layer is arranged, in some embodiments sandwiched, between the substrate and the photoactive layer.

In some embodiments a method of forming a photoelectrode according to the invention includes providing a substrate. The method also includes forming a conductive layer (supra) above, including on, the substrate. Furthermore the method includes forming a polymer layer made of a conductive polymer above, including on, the contact layer. The method further includes forming a photoactive layer above, including on, the polymer layer. In some embodiments the method also includes forming a polymer layer on the photoactive layer. The polymer layer has a thickness of about 100 nm or less. The polymer layer is typically of a non-conductive polymer. The polymer layer of a thickness of about 100 nm or less defines the surface of the photo electrode.

In order that the invention may be readily understood and put into practical effect, particular embodiments will now be described by way of the following non-limiting examples.

### EXAMPLES

The following examples illustrate the formation and advantages of a polymer layer according to the present invention.

### Example 1

### Sample Preparation of a Parylene® Layer on ITO Coated Glass

Indium Tin Oxide (ITO) coated glass with a sheet resistance of 20 ohm per square was used. The routine cleaning procedure that included sonication (in acetone and methanol) and oxygen plasma was carried out. The 10 nm thin insulating Parylene® layer of Parylene C deposited in room temperature by CVD was formed essentially free of pinholes by chemical vapour deposition (CVD) in a reactor set at a base pressure 0.1 Torr at room temperature. Uniform insulating layers could be formed with precisely controlled thickness in the nanometer range.

### 1.1 Surface Roughness of the Parylene® Layer

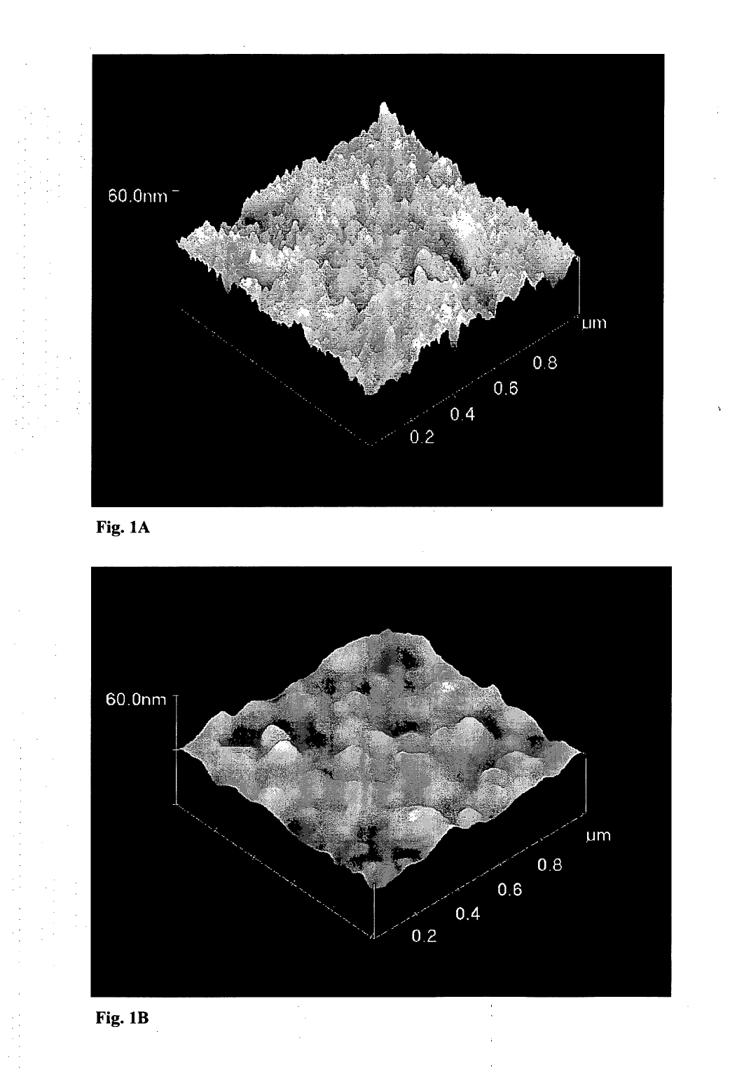

The surface morphology and rms surface roughness were characterized by DI NanoScope IV Multimode Atomic Force Microscope (AFM) from Digital Instruments in tapping mode. The samples were scanned over an area of 1 μm2 at a tip velocity of 2 μm/s and a corresponding scan rate of 1 Hz. AFM results in FIG. 1 show the top morphology of the ITO surface (FIG. 1A) and the 10 nm Parylene®/ITO surface (FIG. 1B) over an area of 1×1 μm. The thick sharp spikes of approximately 10 nm high were observed on the bare ITO surface. However, the bilayer ITO/Parylene® surface exhibited a much more even surface with the roughness reduced to 6.7 nm. More importantly, the Parylene® layer showed an undulated morphology with no sharp spikes. Such a smoothen interfacial layer in between the ITO anode and photoactive layer effectively removes sharp protrusion of materials across the interface and leads to a significant improvement in the carrier injection efficiency and current uniformity. The undulating profile of the Parylene® surface not only provides a good organic-metal oxide adhesion but also increases the area of contact in between the ITO anode and photoactive layer. All these effects shall, in turn, increase the quantum efficiency and lifetime of the PEC electrode.

### 1.2 Optical Transmission/Absorption of the Parylene® Layer

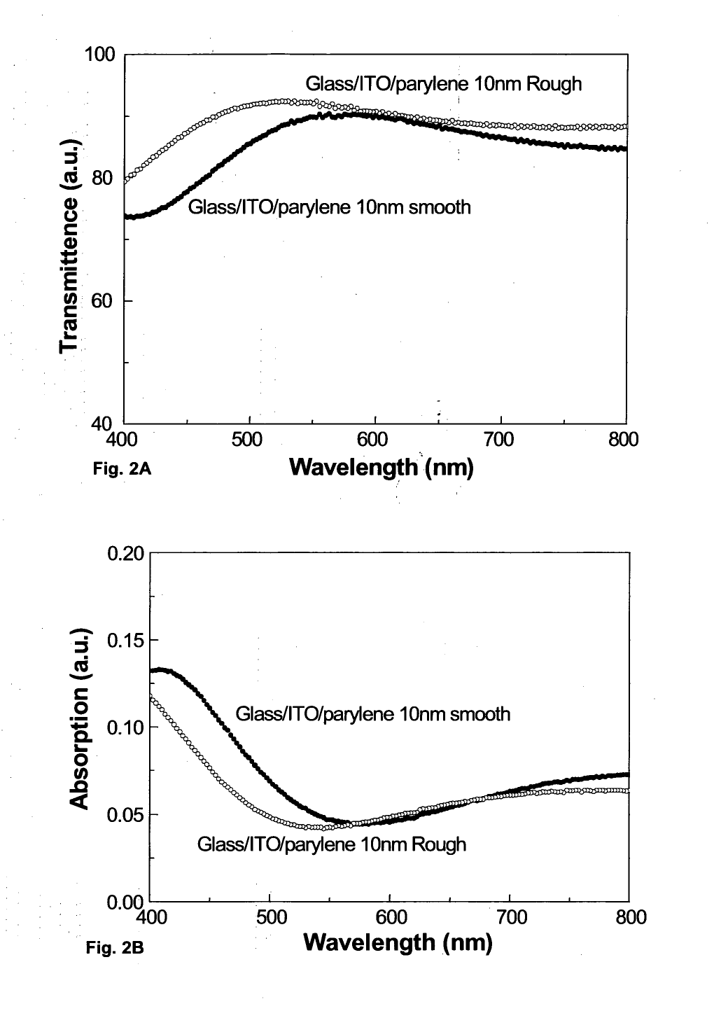

The optical transmission and absorption test is carried out by means of UV-VIS spectroscopy on the Parylene® layers of two different surfaces, differing in roughness. The transmittance results in FIG. 2A showed that a roughened surface exhibited a better transmission in the UV, visible and Infra-red spectrum as compared to a smooth surface. A similar property can also be observed in FIG. 2B, which shows the absorption curve in the same optical spectrum. Such a property is highly desirable as the polymer must not hinder the transmission of light to the photoactive layer if it is to be deployed as the outer protective layer for the photoelectrode against chemical corrosion. Furthermore, the results implied that it is possible to optimize the transmittance property of the photoelectrode via controlling the surface roughness of the protective polymer layer which has the effects of reflecting light into the photoactive layer.

### 1.3 UPS Surface Work Function Test

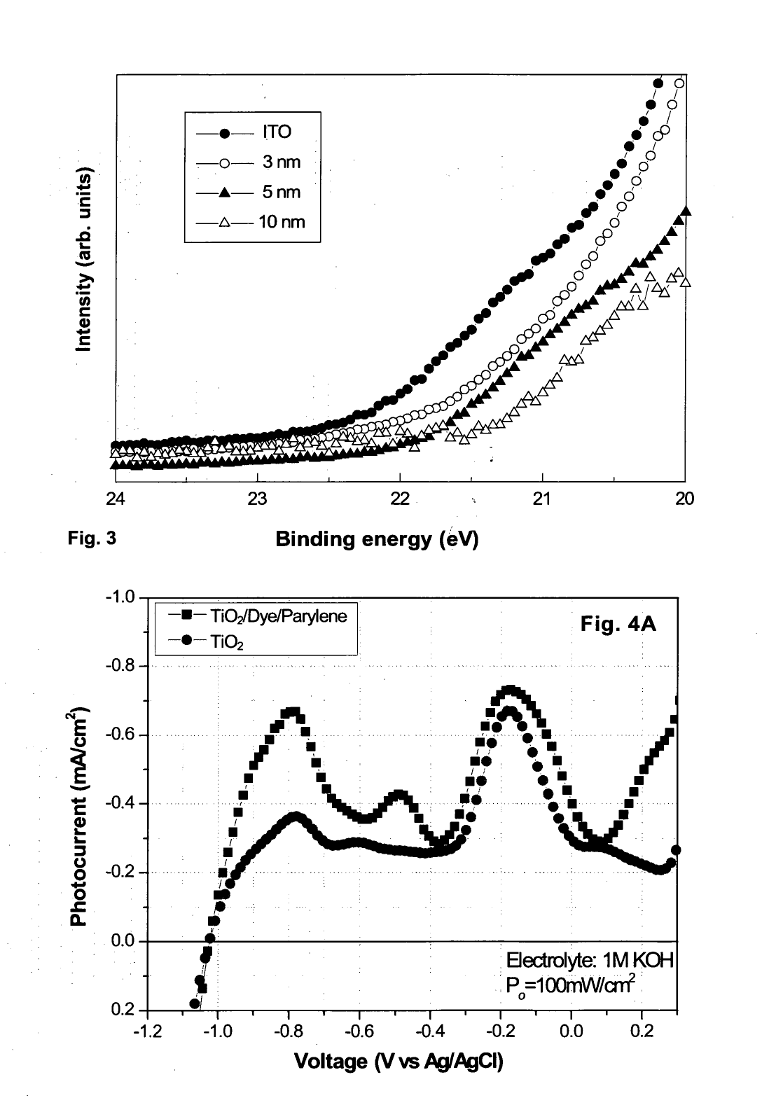

From the AFM experiments, it was demonstrated that ITO surface with a thin Parylene® coating showed no sharp spikes. The smoothened interface provided a repeatable clean surface for the subsequent layer deposition with good adhesion. It also improved carrier injection into the electrode and controlled the recombination process. This explained the improved efficiency and lifetime using the transparent organic Parylene® interlayer shown later in the device part. In order to ascertain the mechanism of the improved characteristics, ESCALab ultraviolet photoelectron spectroscopy (UPS) was performed on the ITO surface and on the Parylene® surface. For UPS measurements, He I (hv=21.22 eV) was used as the excitation source and the samples were −10V biased. The UPS results in FIG. 3 demonstrated that the workfunction of the 3 nm thick Parylene® surface had increased by about 0.1 eV compared to that of the bare ITO surface. The barrier for hole injection had thus been reduced.

One possible mechanism for these enhancements could be explained by the tunnelling of carriers through the Parylene® layers. With a reduction of 0.1 eV in the energy offset between the work function of ITO and the following polymer HOMO level, carriers flowed more easily through the interface. For the best device performance, the polymer electrode interface should not impede carrier injection. This is the case when the work function of the anode equals the ionization potential of the polymer (HOMO) and the work function of the cathode equals the electron affinity of the polymer (LUMO). When the Parylene® layer was thin enough for carrier to tunnel through and, in conjunction with the 0.1 eV energy-offset reduction and a smoother interface, hole injection current could be considerably increased. Distribution across the anode injection, therefore, resulted in an improvement in the balance of the holes and electrons injections.

### Example 2

### Preparation of Samples and System Setup

In the prototype for testing, a layer of Parylene® was deposited on the surface of a water splitting photoelectrochemical cell electrode to form the structure of glass/ITO/photoactive layer/Parylene® according to the first example. The PEC system was then completed with a platinum counter electrode and potassium hydroxide (KOH) electrolyte.

The fabrication process began by growing the photoactive TiO₂ layer on cleaned glass/ITO squared shaped substrates of 1.75×1.75 cm. TiO₂ powder (Degussa P-25 containing mostly in anatase form of TiO₂) was sonicated in 1% acetic acid methanol solution to obtain a 5 mg/mL TiO₂ suspension. The suspension was spread on the glass/ITO electrodes by dropwise addition with the aid of a microsyringe. Each drop-wise addition step was followed by air-stream drying to accelerate the evaporation of the solvent. This procedure continued until a desired amount of TiO₂ was spread over the electrodes. Next, the resulting TiO₂ film was annealed in a furnace at 450° C. for 30 minute. The sample was then immersed into an ethanolic solution of N3 dye (Solaronix, Aubonne, Switzerland) for about half an hour at 50° C. and dehydrated again at 80° C. for around 20 minutes. Finally a Parylene® layer of less than 100 nm was deposited on top of the outermost surface of the PEC electrode to serve as the protective coating according to Example 1.

### 2.1 I-V Test Results

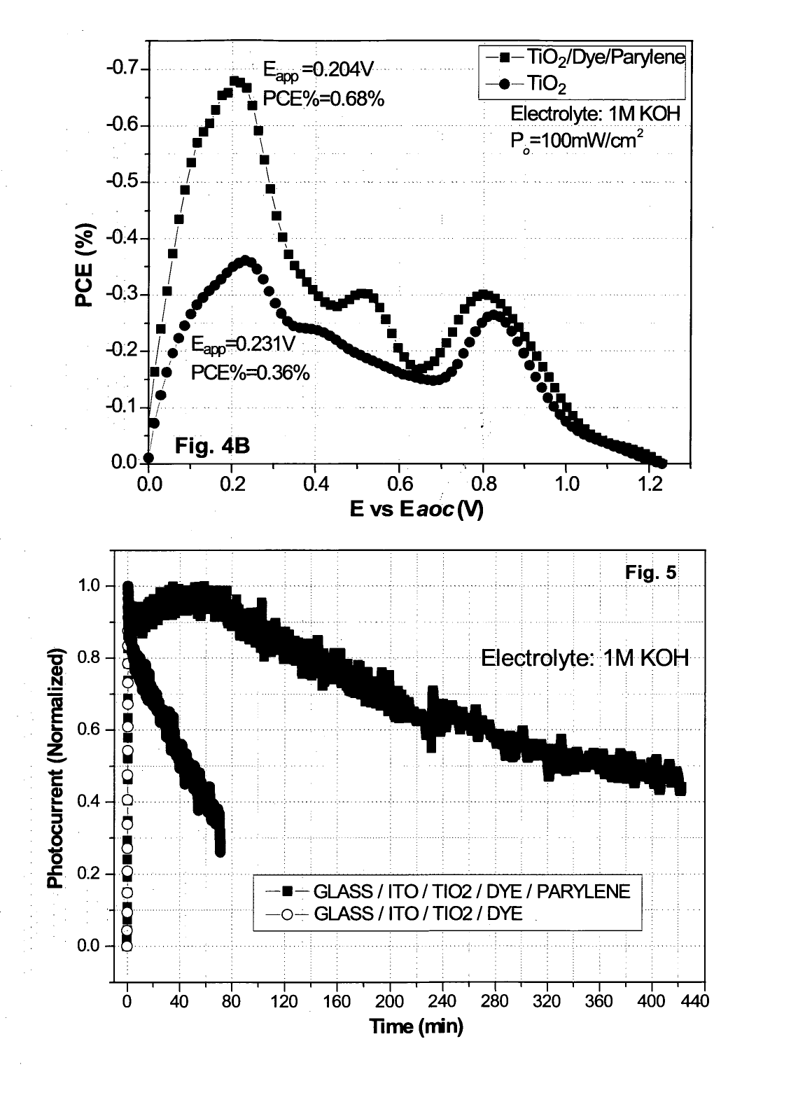

The dye-sensitized TiO₂ based photoelectrode with Parylene® outerlayer was characterized under simulated AM 1.5G sunlight with an intensity of 100 mW/cm². FIG. 4 shows the I-V curve of a photoelectrode under the enhancement effects of the Parylene® outerlayer. The I-V characteristics of the bare photoelectrode (glass/ITO/TiO₂) under light and dark conditions are also shown for comparison.

The results depicted in FIG. 4 show that the TiO₂ dye-sensitized photoelectrode with Parylene® outer coating delivered high conversion efficiency as compared to the non-dye TiO₂ bare photoelectrode (glass/ITO/TiO₂). At a slight voltage bias of 0.204V, the current density and photoconversion efficiency of the TiO₂ dye-sensitized photoelectrode with polymer coating was almost twice the amount of the non-dye counterpart. Without the intent of being bound by theory, this experimental result could be explained with that typical TiO₂ based photoelectrode exhibited a poor absorption of light due to its large bandgap. While the incorporation of dye layer (dye-sensitizing) was effective in improving spectral absorption, the technique was severely handicapped by the rapid dissolution of dye upon contact with the electrolyte. The implication of the experimental result is significant as it showed that the Parylene® coating could be used with the dye layer to bring about a considerable improvement in the efficiency of the PEC. The embodiment, thus, offers a practical solution to resolve the problems of dye degradation in water splitting photoelectrochemical cells and DSSCs.

The photoelectrodes were connected with a Pt foil and a standard Ag/AgCl reference electrode to form a conventional 3-arm electrolytic system. The electrolyte used comprised of 1M KOH solution. The system was characterized under a Xe lamp (Oriel) at 100 mW/cm² with a filter (>300 nm). The potential of the photoelectrode versus the reference electrode was controlled by the potentiostat (263A, Princeton Applied Research) during I-V characterization.

### 2.2 Operational Lifetime Measurement

With the Parylene® film as a protective layer, the PEC cell functioned well and its lifetime was improved significantly. FIG. 5 shows the lifetime curves of glass/ITO/TiO₂/Dye/Parylene®and glass/ITO/TiO₂/Dye obtained at zero voltage potential versus Ag/AgCl electrode. From the graph, it can be observed that as the photoelectrode with Parylene® outer-layer coating operated continuously for more than 400 minutes, the photocurrent density dropped gradually from 0.07 mA/cm2 to 0.035 mA/cm², which is a reduction of almost 50%. The photoelectrode with the Parylene® outer-layer is expected to continue operation beyond 400 minutes if the light remained on in the experiment. On the other hand, without the Parylene® outer-layer coating, the photoelectrode exhibited a much more drastic reduction in the photocurrent during the course of operation. The photocurrent density dropped from 0.04 mA/cm² to less than 0.02 mA/cm², in less than 60 minutes to about 50% of its original value. As the photoelectrodes were inspected visually, it could be observed that the dye layer of the unprotected electrode experienced significant corrosion while the one with Parylene® outer coating remained intact.

The graph of operation lifetime above had shown the effectiveness of the Parylene® outerlayer coating in protecting the dye layer against corrosion. While providing the shield against the corrosive effects from the electrolyte, the Parylene® also stabilized the dye and TiO₂ layer and improved the injection of holes into the electrolyte. Without the Parylene® outer coating, corrosion started taking effect immediately upon operation, and might induce defects into the dye and TiO₂ structure. This explained the observation that the photocurrent density of the unprotected electrode was much lower than that of the Parylene® coated electrode even at the onset of operation.

### 2.3 Optical Absorption Measurement

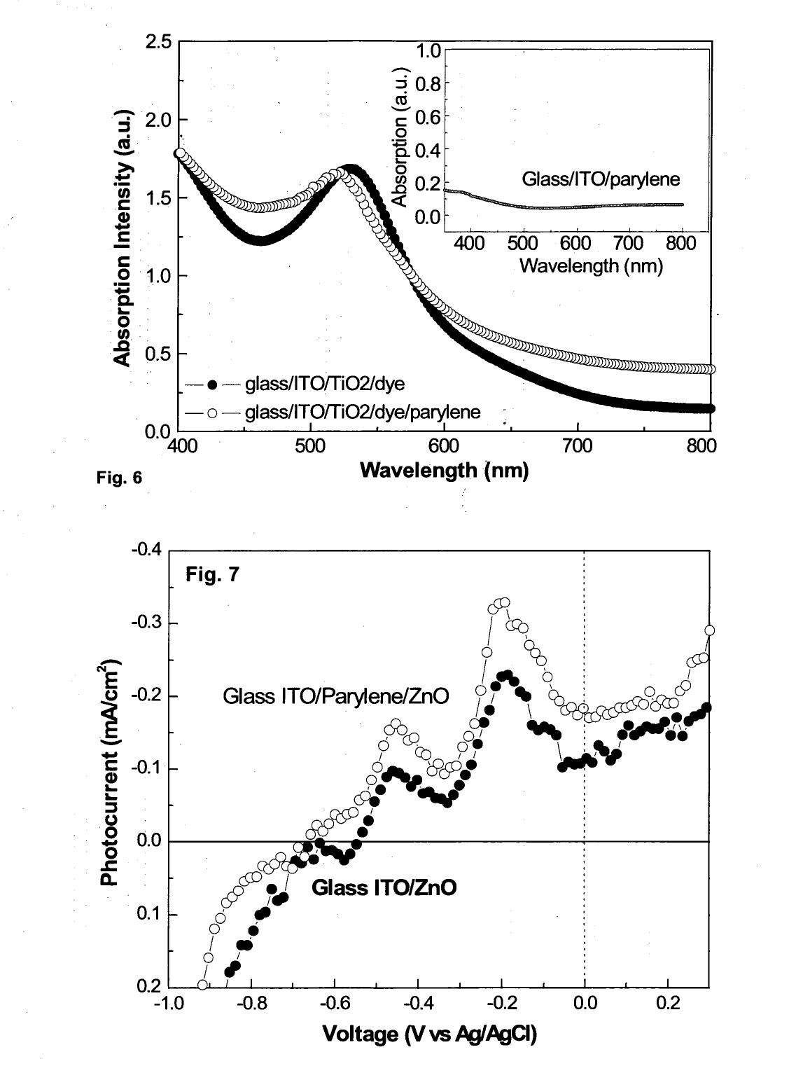

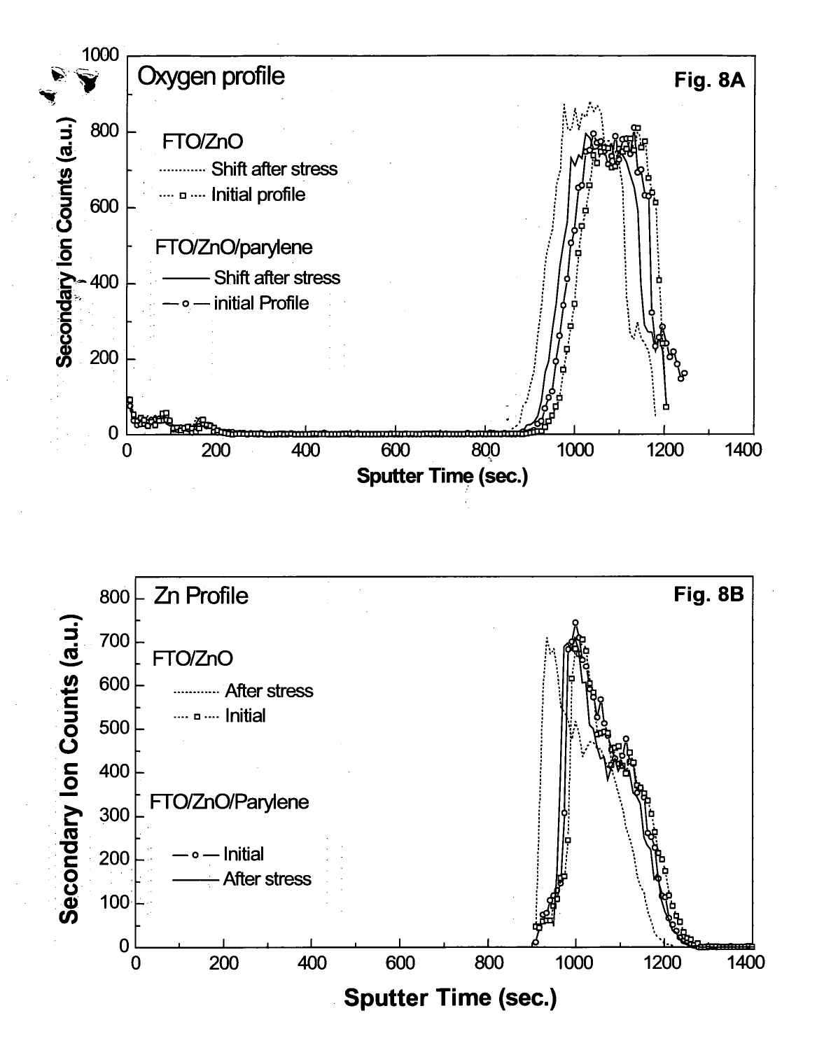

The absorption spectra of the dyes adsorbed by TiO₂ films were measured with a Shimadzu UV-3101 PC spectrophotometer. FIG. 6 showed the typical UV-Vis absorbance spectra of glass/ITO/TiO₂/dye and glass/ITO/TiO₂/dye/Parylene®. The visible range absorption peak around 550 nm was due to dye absorption. The dye with Parylene® sample has slightly higher absorption in longer wavelength larger than 600 nm and around 450 nm. In contrast thereto, the glass/ITO/TiO₂/dye had little absorption in the visible range. The glass/ITO/TiO₂/dye/Parylene® absorption spectral has been corrected by glass/TIO₂/Parylene®absorption spectral (inset of FIG. 6), which means that the improvement of the absorption in the visible range is due to the re-absorption of TiO₂/dye layer by light reflection of Parylene® layer.

The PEC cell incorporated with dye had improved the absorption as could been seen from FIG. 6. With proper control on the surface roughness of the Parylene® outer layer, more light could be reflected back to the photoactive layer to further optimize the spectral absorption in the PEC electrode.

### Example 3

### Effectiveness of a Parylene® Interlayer in Enhancing Efficiency of the Photoelectrode

A thin Parylene® interlayer of thickness in the order of 10 nm was deposited in between the ITO anode layer and photoactive ZnO layer to form a photoelectrode with the structure of ITO/Parylene®/photoactive layer. The solution for the photoactive layer was developed by dissolving zinc acetate dihydrate in methanol under vigorous stirring at 60° C. and then adding KOH in methanol dropwise for 10 min at 60° C. and stirring for 2 h at 60° C.

The experimental results shown in FIG. 7 showed that, with the Parylene® interlayer, the photoelectrode delivered higher conversion efficiency. At a slight voltage bias of 0.2V, the photoelectrode with polymer interlayer coating was almost 1.5 times of that of the counterpart. Without the intent of being bound by theory, an explanation of this result could be the smoothened interface provided by the polymer interlayer between the ITO anode layer and the photoactive ZnO layer. This smoothened interface may have led to a more homogenous current flow across the interface. Furthermore, the polymer interface provided a stronger polymer to metal oxide bond. All these factors effectively reduce the barrier for carrier injection across the interface. Hence, a higher conversion efficiency could be achieved.

### 4 Mass Spectrometry

Secondary Ion Mass Spectroscopy was carried out on IONTOF at room temperature to look into the effect of Parylene® on enhancing the stability ZnO substrate used in DSSC and PEC electrode. It has been observed on the structure: glass/FTO/ZnO/Parylene®:

The O and Zn profile become very stable after hours of stress, as compared the structure without parlene layer. The results indicate that the Parylene® thin film had effectively stabilized the ZnO structure subjected to prolong stress condition. The stable structure shall lead much longer lifetime of the photoelectrode.

The above data prove that the technique of the invention is effective on an electrode in liquid-based electrolyte, so that it can be applied on conventional DSSCs and water-splitting PEC system.

A photoelectrode according to the invention allows the use of many insulating polymers including Parylene® or even PVDF as protective coating for electrodes. Prior to this method, we were unable to exploit many useful properties of these materials relevant for use as protective coating due to their electrically-insulating nature.

The listing or discussion of a previously published document in this specification should not necessarily be taken as an acknowledgement that the document is part of the state of the art or is common general knowledge.

The invention has been described broadly and generically herein. Each of the narrower species and subgeneric groupings falling within the generic disclosure also form part of the invention. This includes the generic description of the invention with a proviso or negative limitation removing any subject matter from the genus, regardless of whether or not the excised material is specifically recited herein.

One skilled in the art would readily appreciate that the present invention is well adapted to carry out the objects and obtain the ends and advantages mentioned, as well as those inherent therein. Further, it will be readily apparent to one skilled in the art that varying substitutions and modifications may be made to the invention disclosed herein without departing from the scope and spirit of the invention. The molecular complexes and the methods, procedures, treatments, molecules, specific compounds described herein are presently representative of preferred embodiments are exemplary and are not intended as limitations on the scope of the invention. Changes therein and other uses will occur to those skilled in the art which are encompassed within the spirit of the invention are defined by the scope of the claims.

The invention illustratively described herein suitably may be practiced in the absence of any element or elements, limitation or limitations which is not specifically disclosed herein. Thus, for example, in each instance herein any of the terms “comprising”, “consisting essentially of” and “consisting of” etc. shall be read expansively and without limitation, and are not limited to only the listed components they directly reference, but include also other non-specified components or elements. As such they may be exchanged with each other. Additionally, the terms and expressions which have been employed are used as terms of description and not of limitation, and there is no intention that in the use of such terms and expressions of excluding any equivalents of the features shown and described or portions thereof, but it is recognized that various modifications are possible within the scope of the invention claimed.

Other embodiments are within the following claims. In addition, where features or aspects of the invention are described in terms of Markush groups, those skilled in the art will recognize that the invention is also thereby described in terms of any individual member or subgroup of members of the Markush group.

What is claimed is:

1. A photoelectrode comprising at least one polymer layer, wherein the at least one polymer layer is made of a non-conductive polymer and has a thickness of about 100 nm or less, wherein the at least one polymer layer (i) defines the surface of the photoelectrode, (ii) defines an interlayer within the photoelectrode, or (iii) both.

2. The photoelectrode according to claim 1, further comprising a substrate.

3. The photoelectrode according to claims 2, further comprising a conductive layer, wherein at least a portion of the conductive layer is in contact with the substrate.

4. The photoelectrode according to claim 3, wherein the conductive layer comprises a transparent conductive metal oxide.

5. The photoelectrode according to any one of claims 2-4, wherein at least a portion of the polymer layer is in contact with the conductive layer.

6. The photoelectrode according to any one of claims 2-5, wherein the conductive layer is arranged between the substrate and the polymer layer

7. The photoelectrode according to claim 6, wherein the conductive layer is sandwiched between the substrate and the polymer layer.

8. The photoelectrode according to any one of claims 2-7, further comprising a photoactive layer, wherein the conductive layer is arranged between the substrate and the photoactive layer.

9. The photoelectrode according to claim 8, wherein the photoactive layer comprises a semiconductor.

10. The photoelectrode according to claim 9, wherein the semiconductor is a metal oxide or a metalloid oxide.

11. The photoelectrode according to any one of claims 8-10, wherein the photoelectrode is a dye-sensitized photoelectrode and wherein the photoactive layer comprises a chromophore.

12. The photoelectrode according to claim 11, wherein photoactive layer comprises a semiconductor and a chromophore, wherein the chromophore is in contact with the semiconductor.

13. The photoelectrode according to any one of claims 8 to 12, wherein at least a portion of the photoactive layer is in contact with the polymer layer.

14. The photoelectrode according to claim 13, wherein the polymer layer defines an interlayer within the photoelectrode and wherein the polymer layer is arranged between the conductive layer and the photoactive layer.

15. The photoelectrode according to claim 14, wherein the polymer layer is sandwiched between the conductive layer and the photoactive layer.

16. The photoelectrode according to claim 13, wherein the polymer layer defines the surface of the photoelectrode and wherein the photoactive layer is arranged between the conductive layer and the polymer layer.

17. The photoelectrode according to claim 16, further comprising a conductive polymer layer arranged between the conductive layer and the photoactive layer, such that the photoactive layer is sandwiched between the conductive polymer layer and the non-conductive polymer layer defining the surface of the photoelectrode.

18. The photoelectrode according to any one of claims 1-17, wherein the polymer of the conductive polymer layer is selected from the group consisting of a polycarbazole, poly(N-vinyl carbazole), a polyindole, a polyazepine, a polyaniline, a poly(thiophene), poly(p-phenylene), poly(p-phenylene vinylene), a poly(p-phenylene sulfide), a poly(acetylene), a poly(fluorene), a polypyrene, a polyazulene, and a polynaphthalene.

19. The photoelectrode according to any one of claims 1-18, wherein the polymer of the non-conductive polymer layer is selected from the group consisting of a polyimide, a polyetherimide, a polyether, a polyester, a polyurethane, a polycarbonate, a polysulfone, a polyethersulfone, polytetrafluoro ethylene, fluoroethylenepropylene, ethyl enetetrafluoro ethylene, tetrafluoroethylene-perfluoromethylvinyl ether, vinylidene fluoride-hexafluoropropyl ene copolymer, tetrafluoro ethylene-hexafluoropropylene copolymer, polyvinylidenedifluoride, vinylidene fluoride-hexafluoropropylene-tetrafluoro ethyl ene terpolymer, perfluoromethyl vinyl ether-tetrafluoroethylen copolymer, perfluoroalkoxy copolymer, poly(vinyl fluoride), polychlorotrifluoroethylene, a fluorosilicone, a fluorophosphazene, a polyimide, poly(1,4-xylylene), poly(2-chloro-p-xylylene), poly(2,5-dichloro-p-xylylene), poly(α,α,α,α-tetrafluoro-p-xylylene), a poly-(amino-p-xylylene), a poly(aminomethyl-p-xylylene), poly(tetrafluoro-p-xylylene) and a combination thereof.

20. The photoelectrode according to any one of claims 1-19, comprising at least two polymer layers, wherein one polymer layer of the at least two polymer layers defines the surface of the photoelectrode, and one polymer of the at least two polymer layers defines an interlayer within the photoelectrode.

21. A method of producing a photoelectrode according to any one of claims 1 to 18, the method comprising
(a) providing a substrate, and
(b) forming a polymer layer above the substrate,
wherein the polymer layer is made of a non-conductive polymer and has a thickness of about 100 nm or less.

22. The method of claim 21, wherein providing the substrate comprises forming a conductive layer above the substrate, wherein the polymer layer is then formed above the conductive layer.

23. The method of claim 22, wherein forming a conductive layer above the substrate comprises depositing the conductive layer on the substrate such that at least a portion of the conductive layer is in contact with the substrate.

24. The method of claim 22 or 23, wherein forming the polymer layer comprises depositing the non-conductive polymer on the conductive layer, such that at least a portion of the polymer layer is in contact with the conductive layer.

25. The method of any one of claims 22 to 24, further comprising forming a photoactive layer above the conductive layer.

26. The method of claim 25, wherein forming a photoactive layer above the conductive layer comprises depositing the photoactive layer on the polymer layer, such that the photoactive layer defines the surface of the photoelectrode and the polymer layer is arranged between the conductive layer and the photoactive layer.

27. The method of claim 25, wherein forming a photoactive layer above the conductive layer comprises depositing the photoactive layer on the conductive layer, such that the polymer layer defines the surface of the photoelectrode and the photoactive layer is arranged between the conductive layer and the polymer layer.

28. A photoelectrode comprising a photoactive layer, a conductive layer and at least one polymer layer, wherein the at least one polymer layer is made of a conductive polymer and is arranged between the photoactive layer and the conductive layer.

29. The photoelectrode of claim 28, wherein the photoelectrode further comprises a substrate.

30. The photoelectrode of claim 28 or 29, wherein the at least one polymer layer comprises or consists of a conductive polymer selected from the group consisting of polypyrrol, a polycarbazole, poly(N-vinyl carbazole), a polyindole, a polyazepine, a polyaniline, a poly(thiophene), poly(p-phenylene), poly(p-phenylene vinylene), a poly(p-phenylene sulfide), a poly(acetylene), a poly(fluorene), a polypyrene, a polyazulene, and a polynaphthalene.

31. A method of producing a photoelectrode according to any one of claims 27 to 30, the method comprising
(a) providing a substrate,
(b) forming a conductive layer above the substrate,
(c) forming a polymer layer made of a conductive polymer above the conductive layer; and
(d) forming a photoactive layer above the polymer layer.

32. The method of claim 31, further comprising forming a polymer layer made of a non-conductive polymer with a thickness of about 100 nm or less on the photoactive layer, wherein this polymer layer made of a non-conductive polymer defines the surface of the photoelectrode.

33. A photoelectrochemical cell comprising a photoelectrode according to any one of claim 1-20 or 28-30.

34. The photoelectrochemical cell of claim 33, being selected from the group consisting of a photovoltaic cell and a water splitting photoelectrochemical cell.
